(19) United States
(12) Patent Application Publication
(10) Pub. No.: US 2020/0176661 A1
(43) Pub. Date: Jun. 4, 2020

(54) SERIES-PARALLEL CLUSTER CONFIGURATION OF A THIN-FILM BASED THERMOELECTRIC MODULE

(71) Applicant: Sridhar Kasichainula, Fremont, CA (US)

(72) Inventor: Sridhar Kasichainula, Fremont, CA (US)

(21) Appl. No.: 16/779,668

(22) Filed: Feb. 3, 2020

Related U.S. Application Data
(63) Continuation-in-part of application No. 15/808,902, filed on Nov. 10, 2017.
Application No. 15/808,902 is a continuation-in-part of application No. 14/564,072, filed on Dec. 8, 2014, now abandoned.
Application No. 15/808,902 is a continuation-in-part of application No. 14/711,810, filed on May 14, 2015, now Pat. No. 10,141,492.
Application No. 14/711,810 is a continuation-in-part of application No. 15/368,683, filed on Dec. 5, 2016, now Pat. No. 10,290,794.
(60) Provisional application No. 61/912,561, filed on Dec. 6, 2013.

(51) Int. Cl. H01L 35/34; C23C 14/34; H01L 35/32

(52) U.S. Cl. CPC H01L 35/34; H01L 35/32; C23C 14/34

(57) ABSTRACT

A method includes sputter depositing a first cluster and a second cluster of pairs of N-type thermoelectric legs and P-type thermoelectric legs electrically in contact with one another on a flexible substrate. The flexible substrate has a dimensional thickness less than or equal to 25 μm. Within the first cluster and the second cluster, the pairs are electrically connected to one another in series or parallel. The method also includes electrically connecting the sputter deposited first cluster and the sputter deposited second cluster also in series or parallel across the flexible substrate to form a thin-film based thermoelectric module, and rendering the formed thin-film based thermoelectric module flexible and less than or equal to 100 μm in dimensional thickness based on choices of fabrication processes with respect to layers of the formed thin-film based thermoelectric module including the sputter deposited first cluster and the sputter deposited second cluster.

### CLAIM OF PRIORITY

This application is a Continuation-in-Part application of co-pending U.S. patent application Ser. No. 15/808,902 titled FLEXIBLE THIN-FILM BASED THERMOELECTRIC DEVICE WITH SPUTTER DEPOSITED LAYER OF N-TYPE AND P-TYPE THERMOELECTRIC LEGS filed on Nov. 10, 2017, which is a Continuation-in-Part application of U.S. patent application Ser. No. 14/564,072 titled VOLTAGE GENERATION ACROSS TEMPERATURE DIFFERENTIALS THROUGH A THERMOELECTRIC LAYER COMPOSITE filed on Dec. 8, 2014, which is a conversion application of U.S. Provisional Application No. 61/912,561 also titled VOLTAGE GENERATION ACROSS TEMPERATURE DIFFERENTIALS THROUGH A THERMOELECTRIC LAYER COMPOSITE filed on Dec. 6, 2013, U.S. patent application Ser. No. 14/711,810 titled ENERGY HARVESTING FOR WEARABLE TECHNOLOGY THROUGH A THIN FLEXIBLE THERMOELECTRIC DEVICE filed on May 14, 2015 and issued as U.S. Pat. No. 10,141,492 on Nov. 27, 2018, and U.S. patent application Ser. No. 15/368,683 titled PIN COUPLING BASED THERMOELECTRIC DEVICE filed on Dec. 5, 2016 and issued as U.S. Pat. No. 10,290,794 on May 14, 2019. The contents of the aforementioned applications are incorporated by reference in entirety thereof.

### FIELD OF TECHNOLOGY

This disclosure relates generally to thermoelectric devices and, more particularly, to a series-parallel cluster configuration of a thin-film based thermoelectric module.

### BACKGROUND

A thermoelectric device may be formed from alternating N and P elements/legs made of semiconducting material on a rigid substrate (e.g., alumina) joined on a top thereof to another rigid substrate/plate (e.g., again, alumina). Addition of more sets of N and P elements/legs in series in a bulk thermoelectric module formed out of the aforementioned alternating N and P elements/legs may lead to increased series resistance, thereby lowering an output current of the bulk thermoelectric module to non-functional levels.

### SUMMARY

Disclosed are methods, a device and/or a system of a series-parallel cluster configuration of a thin-film based thermoelectric module.

In one aspect, a method includes sputter depositing a first cluster of pairs of N-type thermoelectric legs and P-type thermoelectric legs electrically in contact with one another on a first surface of a flexible substrate. The flexible substrate is aluminum (Al) foil, a sheet of paper, polytetrafluoroethylene, polyimide, plastic, a single-sided copper (Cu) clad laminate sheet, or a double-sided Cu clad laminate sheet. The flexible substrate has a dimensional thickness less than or equal to 25 μm, and the pairs of the first cluster are electrically connected to one another in a first series or a first parallel. The method also includes sputter depositing a second cluster of pairs of N-type thermoelectric legs and P-type thermoelectric legs electrically in contact with one another on the first surface of the flexible substrate, with the pairs of the second cluster being electrically connected to one another in a second series or a second parallel, and electrically connecting the sputter deposited first cluster and the sputter deposited second cluster in a third series or a third parallel across the first surface to form a thin-film based thermoelectric module.

Further, the method includes rendering the formed thin-film based thermoelectric module flexible and less than or equal to 100 μm in dimensional thickness based on choices of fabrication processes with respect to layers of the formed thin-film based thermoelectric module including the sputter deposited first cluster and the sputter deposited second cluster. The flexibility enables the formed thin-film based thermoelectric module to be completely wrappable and bendable around a system element from which the formed thin-film based thermoelectric module is configured to derive thermoelectric power, and a layer of the formed thin-film based thermoelectric module including the sputter deposited N-type thermoelectric legs and the P-type thermoelectric legs of the pairs of the first cluster and the pairs of the second cluster has a dimensional thickness less than or equal to 25 μm.

In another aspect, a method includes sputter depositing a first cluster of pairs of N-type thermoelectric legs and P-type thermoelectric legs electrically in contact with one another on a first surface of a flexible substrate. The flexible substrate is Al foil, a sheet of paper, polytetrafluoroethylene, polyimide, plastic, a single-sided Cu clad laminate sheet, or a double-sided Cu clad laminate sheet. The flexible substrate has a dimensional thickness less than or equal to 25 μm, and the pairs of the first cluster are electrically connected to one another in a first series or a first parallel. The method also includes sputter depositing a second cluster of pairs of N-type thermoelectric legs and P-type thermoelectric legs electrically in contact with one another on the first surface of the flexible substrate, with the pairs of the second cluster being electrically connected to one another in a second series or a second parallel, electrically connecting the sputter deposited first cluster and the sputter deposited second cluster in a third series or a third parallel across the first surface to form a thin-film based thermoelectric module, and encapsulating the formed thin-film based thermoelectric module with an elastomer to render flexibility thereto.

The elastomer provides an encapsulation having a dimensional thickness less than or equal to 15 μm. Further, the method includes additionally rendering the encapsulated formed thin-film based thermoelectric module flexible and less than or equal to 100 μm in dimensional thickness based on choices of fabrication processes with respect to layers of the encapsulated formed thin-film based thermoelectric module including the sputter deposited first cluster and the sputter deposited second cluster. The additional flexibility enables the encapsulated formed thin-film based thermoelectric module to be completely wrappable and bendable around a system element from which the encapsulated formed thin-film based thermoelectric module is configured to derive thermoelectric power, and a layer of the encapsulated formed thin-film based thermoelectric module including the sputter deposited N-type thermoelectric legs and the P-type thermoelectric legs of the pairs of the first cluster and the pairs of the second cluster has a dimensional thickness less than or equal to 25 μm.

In yet another aspect, a method includes sputter depositing a first cluster of pairs of N-type thermoelectric legs and P-type thermoelectric legs electrically in contact with one another on each of a first surface and a second surface of a flexible substrate. The flexible substrate is Al foil, a sheet of paper, polytetrafluoroethylene, polyimide, plastic, a single-sided Cu clad laminate sheet, or a double-sided Cu clad laminate sheet. The flexible substrate has a dimensional thickness less than or equal to 25 μm, and the pairs of the first cluster are electrically connected to one another in a first series or a first parallel. The method also includes sputter depositing a second cluster of pairs of N-type thermoelectric legs and P-type thermoelectric legs electrically in contact with one another on the each of the first surface and the second surface of the flexible substrate, with the pairs of the second cluster being electrically connected to one another in a second series or a second parallel, and electrically connecting the sputter deposited first cluster on the each of the first surface and the second surface and the sputter deposited second cluster on the each of the first surface and the second surface in a third series or a third parallel across the each of the first surface and the second surface to form a thin-film based thermoelectric module.

Further, the method includes rendering the formed thin-film based thermoelectric module flexible and less than or equal to 100 μm in dimensional thickness based on choices of fabrication processes with respect to layers of the formed thin-film based thermoelectric module including the sputter deposited first cluster and the sputter deposited second cluster. The flexibility enables the formed thin-film based thermoelectric module to be completely wrappable and bendable around a system element from which the formed thin-film based thermoelectric module is configured to derive thermoelectric power, and a layer of the formed thin-film based thermoelectric module including the sputter deposited N-type thermoelectric legs and the P-type thermoelectric legs of the pairs of the first cluster and the pairs of the second cluster has a dimensional thickness less than or equal to 25 μm.

Other features will be apparent from the accompanying drawings and from the detailed description that follows.

### BRIEF DESCRIPTION OF THE DRAWINGS

The embodiments of this invention are illustrated by way of example and not limitation in the figures of the accompanying drawings, in which like references indicate similar elements and in which:

FIG. 1 is a schematic view of a thermoelectric device.

FIG. 2 is a schematic view of an example thermoelectric device with alternating P and N elements.

FIG. 3 is a top schematic view of a thermoelectric device component, according to one or more embodiments.

FIG. 4 is a process flow diagram detailing the operations involved in realizing a patterned flexible substrate of a thermoelectric device as per a design pattern, according to one or more embodiments.

FIG. 5 is a schematic view of the patterned flexible substrate of FIG. 4, according to one or more embodiments.

FIG. 6 is a schematic view of the patterned flexible substrate of FIG. 4 with N-type thermoelectric legs, P-type thermoelectric legs, a barrier layer and conductive interconnects, according to one or more embodiments.

FIG. 7 is a process flow diagram detailing the operations involved in sputter deposition of the N-type thermoelectric legs of FIG. 6 on the patterned flexible substrate (or, a seed metal layer) of FIG. 5, according to one or more embodiments.

FIG. 8 is a process flow diagram detailing the operations involved in deposition of the barrier layer of FIG. 6 on top of the sputter deposited pairs of P-type thermoelectric legs and the N-type thermoelectric legs of FIG. 6 and forming the conductive interconnects of FIG. 6 on top of the barrier layer, according to one or more embodiments.

FIG. 9 is a process flow diagram detailing the operations involved in encapsulating the thermoelectric device of FIG. 4 and FIG. 6, according to one or more embodiments.

FIG. 10 is a schematic view of a flexible thermoelectric device embedded within a watch strap of a watch completely wrappable around a wrist of a human being, according to one or more embodiments.

FIG. 11 is a schematic view of a flexible thermoelectric device wrapped around a heat pipe, according to one or more embodiments.

FIG. 12 is a schematic view of example wiring configurations of an example set of four equivalent thermoelectric generators (TEGs) including a series configuration, a parallel configuration and a series-parallel configuration.

FIG. 13 is a schematic view of a two cluster series-parallel configuration of a thermoelectric device component analogous to the thermoelectric device component of FIG. 3, according to one or more embodiments.

FIG. 14 is a schematic view of a four cluster series-parallel configuration of a thermoelectric device component analogous to the thermoelectric device component of FIG. 3, according to one or more embodiments.

FIG. 15 is a schematic view of a six cluster series-parallel configuration of a thermoelectric device component analogous to the thermoelectric device component of FIG. 3, according to one or more embodiments.

FIG. 16 is a schematic front view of a thermoelectric device component in a double-sided substrate configuration, according to one or more embodiments.

FIG. 17 is a process flow diagram detailing the operations involved in realizing a series-parallel cluster configuration of a thin-film based thermoelectric module, according to one or more embodiments.

Other features of the present embodiments will be apparent from the accompanying drawings and from the detailed description that follows.

### DETAILED DESCRIPTION

Example embodiments, as described below, may be used to provide methods, a system and/or a device of a series-parallel cluster configuration of a thin-film based thermoelectric module. Although the present embodiments have been described with reference to specific example embodiments, it will be evident that various modifications and changes may be made to these embodiments without departing from the broader spirit and scope of the various embodiments.

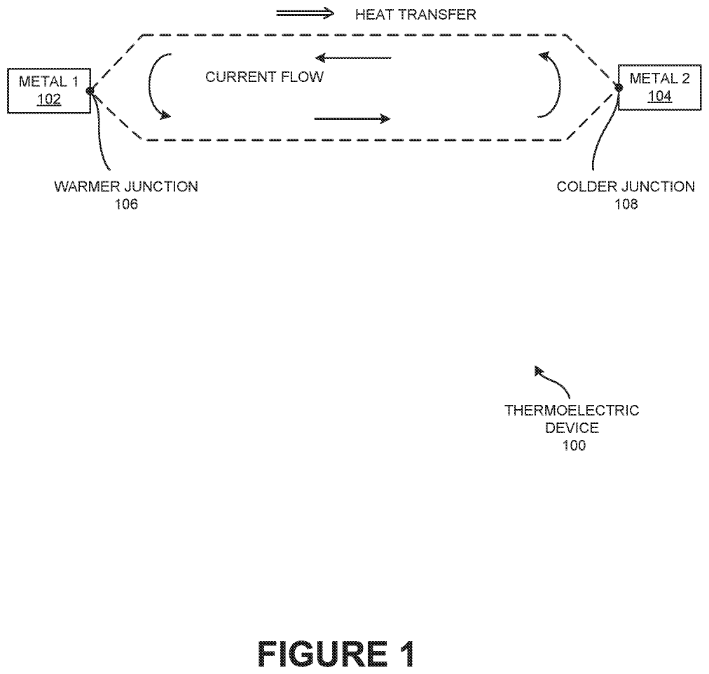

FIG. 1 shows a thermoelectric device 100. Thermoelectric device 100 may include different metals, metal 1 102 and metal 2 104, forming a closed circuit. Here, a temperature difference between junctions of said dissimilar metals leads to energy levels of electrons therein shifted in a dissimilar manner. This results in a potential/voltage difference between the warmer (e.g., warmer junction 106) of the junctions and the colder (e.g., colder junction 108) of the junctions. The aforementioned conversion of heat into electricity at junctions of dissimilar metals is known as Seebeck effect.

The most common thermoelectric devices in the market may utilize alternative P and N type legs/pellets/elements made of semiconducting materials. As heat is applied to one end of a thermoelectric device based on P and N type elements, charge carriers thereof may be released into the conduction band. Electron (charge carrier) flow in the N type element may contribute to a current flowing from the end (hot end) where the heat is applied to the other end (cold end). Hole (charge carrier) flow in the P type element may contribute to a current flowing from the other end (cold end) to the end (hot end) where the heat is applied. Here, heat may be removed from the cold end to prevent equalization of charge carrier distribution in the semiconductor materials due to migration thereof.

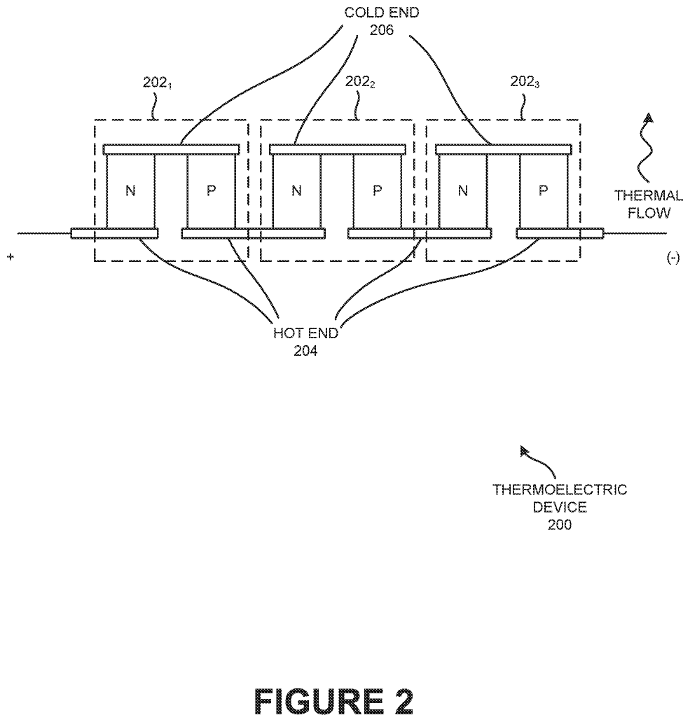

In order to generate voltage at a meaningful level to facilitate one or more application(s), typical thermoelectric devices may utilize alternating P and N type elements (legs/pellets) electrically coupled in series (and thermally coupled in parallel) with one another, as shown in FIG. 2. FIG. 2 shows an example thermoelectric device 200 including three alternating P and N type elements 202₁₋₃. The hot end (e.g., hot end 204) where heat is applied and the cold end (e.g., cold end 206) are also shown in FIG. 2.

Typical thermoelectric devices (e.g., thermoelectric device 200) may be limited in application thereof because of rigidity, bulkiness and high costs (>$20/watt) associated therewith. Also, these devices may operate at high temperatures using active cooling. Exemplary embodiments discussed herein provide for a thermoelectric platform (e.g., enabled via roll-to-roll sputtering on a flexible substrate (e.g., plastic)) that offers a large scale, commercially viable, high performance, easy integration and inexpensive (<20 cents/watt) route to flexible thermoelectrics.

In accordance with the exemplary embodiments, P and N thermoelectric legs may be deposited on a flexible substrate (e.g., plastic) using a roll-to-roll process that offers scalability and cost savings associated with the N and P materials. In a typical solution, bulk legs may have a height in millimeters (mm) and an area in mm². In contrast, N and P bulk legs described in the exemplary embodiments discussed herein may have a height in microns (μm) and an area in the μm² to mm² range.

Examples of flexible substrates may include but are not limited to aluminum (Al) foil, a sheet of paper, polytetrafluoroethylene (e.g., Teflon), plastic, polyimide and a single/double-sided metal (e.g., copper (Cu)) clad laminate. As will be discussed below, exemplary embodiments involve processes for manufacturing/fabrication of thermoelectric devices/modules that enable flexibility thereof not only in terms of substrates but also in terms of thin films/thermoelectric legs/interconnects/packaging. Preferably, exemplary embodiments provide for thermoelectric devices/modules completely wrappable and bendable around other devices utilized in specific applications, as will be discussed below. Further, exemplary embodiments provide for manufactured/fabricated thermoelectric devices/modules that are each less than or equal to 100 μm in dimensional thickness.

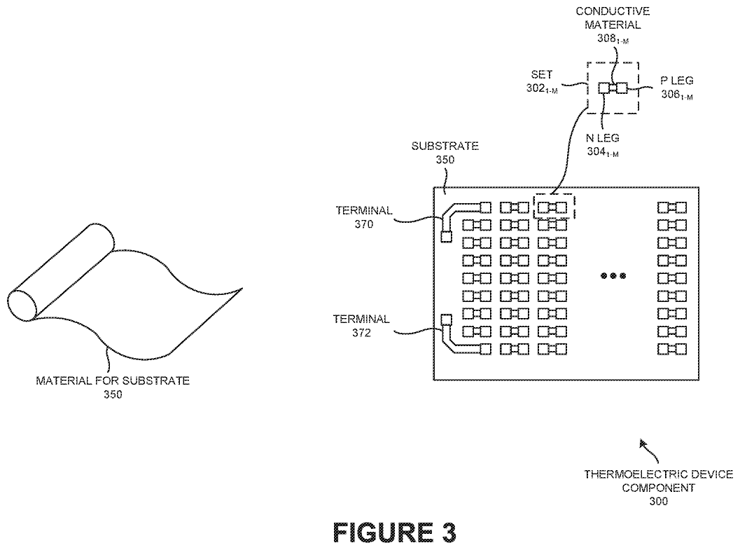

FIG. 3 shows a top view of a thermoelectric device component 300, according to one or more embodiments. Here, in one or more embodiments, a number of sets of N and P legs (e.g., sets 302_{1-M} including N legs 304_{1-M} and P legs 306_{1-M} therein) may be deposited on a substrate 350 (e.g., plastic, metal clad laminate) using a roll-to-roll process discussed above. FIG. 3 also shows a conductive material 308_{1-M} contacting both a set 302_{1-M} and substrate 350, according to one or more embodiments; an N leg 304_{1-M} and a P leg 306_{1-M} form a set 302_{1-M}, in which N leg 304_{1-M} and P leg 306_{1-M} electrically contact each other through conductive material 308_{1-M}. Terminals 370 and 372 may be electrically conductive leads to measure the potential difference generated by a thermoelectric device including thermoelectric device component 300.

Exemplary thermoelectric devices discussed herein may find utility in solar and solar thermal applications. As discussed above, traditional thermoelectric devices may have a size limitation and may not scale to a larger area. For example, a typical solar panel may have an area in the square meter (m²) range and the traditional thermoelectric device may have an area in the square inch range. A thermoelectric device in accordance with the exemplary embodiments may be of varying sizes and/or dimensions ranging from a few mm² to a few m².

Additionally, exemplary thermoelectric devices may find use in low temperature applications such as harvesting body heat in a wearable device, automotive devices/components and Internet of Things (IoT). Entities (e.g., companies, start-ups, individuals, conglomerates) may possess expertise to design and/or develop devices that require thermoelectric modules, but may not possess expertise in the fabrication and packaging of said thermoelectric modules. Alternately, even though the entities may possess the requisite expertise in the fabrication and packaging of the thermoelectric modules, the entities may not possess a comparative advantage with respect to the aforementioned processes.

In one scenario, an entity may create or possess a design pattern for a thermoelectric device. Said design pattern may be communicated to another entity associated with a thermoelectric platform to be tangibly realized as a thermoelectric device. It could also be envisioned that the another entity may provide training with regard to the fabrication processes to the one entity or outsource aspects of the fabrication processes to a third-party. Further, the entire set of processes involving Intellectual Property (IP) generation and manufacturing/fabrication of the thermoelectric device may be handled by a single entity. Last but not the least, the entity may generate the IP involving manufacturing/fabrication of the thermoelectric device and outsource the actual manufacturing/fabrication processes to the another entity.

All possible combinations of entities and third-parties are within the scope of the exemplary embodiments discussed herein.

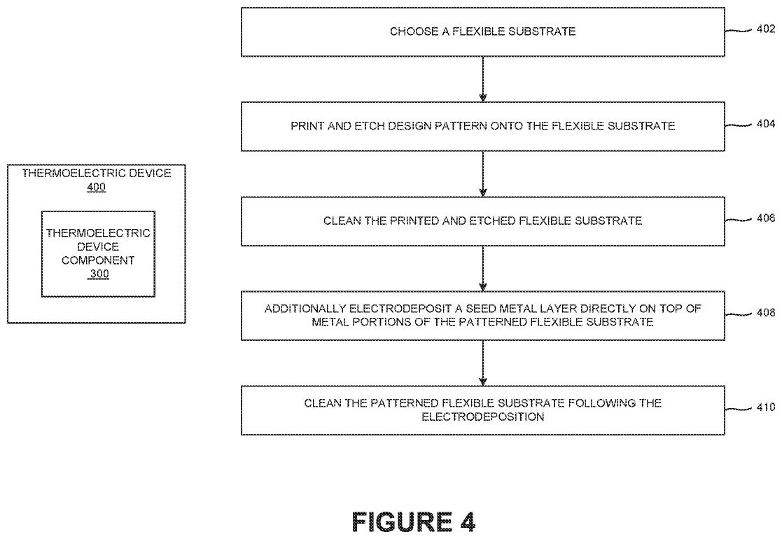

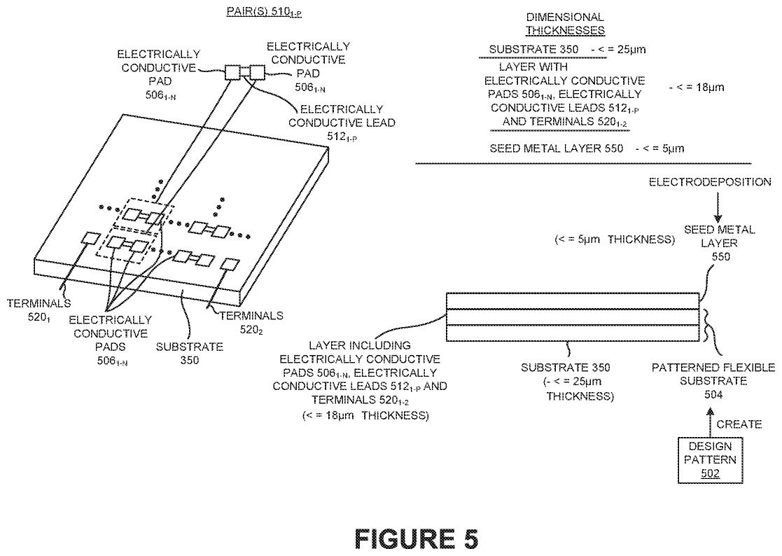

FIG. 4 shows the operations involved in realizing a patterned flexible substrate (e.g., patterned flexible substrate 504 shown in FIG. 5) of a thermoelectric device 400 as per a design pattern (e.g., design pattern 502 shown in FIG. 5), according to one or more embodiments. In one or more embodiments, operation 402 may involve choosing a flexible substrate (e.g., substrate 350) onto which, in operation 404, design pattern 502 may be printed (e.g., through inkjet printing, direct write, screen printing) and etched onto the flexible substrate. In one or more embodiments, a dimensional thickness of substrate 350 may be less than or equal to 25 μm.

Etching, as defined above, may refer to the process of removing (e.g., chemically) unwanted metal (say, Cu) from the patterned flexible substrate. In one example embodiment, a mask (e.g., a shadow mask) or a resist may be placed on portions of the patterned flexible substrate corresponding to portions of the metal that are to remain after the etch. Here, in one or more embodiments, the portions of the metal that remain on the patterned flexible substrate may be electrically conductive pads, electrically conductive leads and terminals formed on a surface of the patterned flexible substrate. FIG. 5 shows a patterned flexible substrate 504 including a number of electrically conductive pads 506_{1-N} formed thereon. Each electrically conductive pad 506_{1-N} may be a flat area of the metal that enables an electrical connection.

Also, FIG. 5 shows a majority set of the electrically conductive pads 506_{1-N} as including pairs 510_{1-P} of electrically conductive pads 506_{1-N} in which one electrically conductive pad 506_{1-N} may be electrically paired to another electrically conductive pad 506_{1-N} through an electrically conductive lead 512_{1—}p also formed on patterned flexible substrate 504; terminals 520₁₋₂ (e.g., analogous to terminals 370 and 372) may also be electrically conductive leads to measure the potential difference generated by the thermoelectric device/module fabricated based on design pattern 502. The aforementioned potential difference may be generated based on heat (or, cold) applied at an end of the thermoelectric device/module.

It should be noted that the configurations of the electrically conductive pads 506_{1-N}, electrically conductive leads 512_{1-P} and terminals 520₁₋₂ shown in FIG. 5 are merely for example purposes, and that other example configurations are within the scope of the exemplary embodiments discussed herein. It should also be noted that patterned flexible substrate 504 may be formed based on design pattern 502 in accordance with the printing and etching discussed above.

Example etching solutions employed may include but are not limited to ferric chloride and ammonium persulphate. Referring back to FIG. 4, operation 406 may involve cleaning the printed and etched flexible substrate. For example, acetone, hydrogen peroxide or alcohol may be employed therefor. Other forms of cleaning are within the scope of the exemplary embodiments discussed herein. In one or more embodiments, the aforementioned processes discussed in FIG. 4 may result in a dimensional thickness of electrically conductive pads 506_{1-N}, electrically conductive leads 512_{1-P} and terminals 520₁₋₂ being less than or equal to 18 μm.

The metal (e.g., Cu) finishes on the surface of patterned flexible substrate 504 may oxidize over time if left unprotected. As a result, in one or embodiments, operation 408 may involve additionally electrodepositing a seed metal layer 550 including Chromium (Cr), Nickel (Ni) and/or Gold (Au) directly on top of the metal portions (e.g., electrically conductive pads 506_{1-N}, electrically conductive leads 512_{1-P}, terminals 520₁₋₂) of patterned flexible substrate 504 following the printing, etching and cleaning. In one or more embodiments, a dimensional thickness of seed metal layer 550 may be less than or equal to 5 μm.

In one example embodiment, surface finishing may be employed to electrodeposit seed metal layer 550; the aforementioned surface finishing may involve Electroless Nickel Immersion Gold (ENIG) finishing. Here, a coating of two layers of metal may be provided over the metal (e.g., Cu) portions of patterned flexible substrate 504 by way of Au being plated over Ni. Ni may be the barrier layer between Cu and Au. Au may protect Ni from oxidization and may provide for low contact resistance. Other forms of surface finishing/electrodeposition may be within the scope of the exemplary embodiments discussed herein. It should be noted that seed metal layer 550 may facilitate contact of sputter deposited N-type thermoelectric legs (to be discussed below) and P-type thermoelectric legs (to be discussed below) thereto.

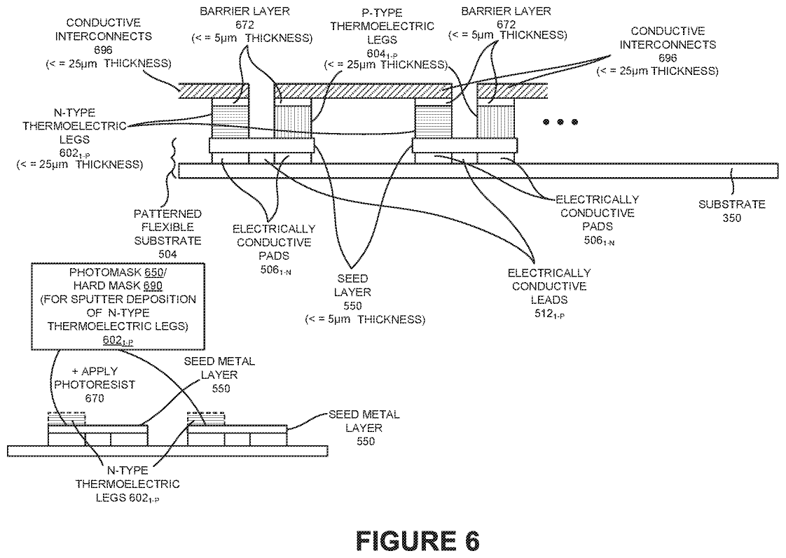

In one or more embodiments, operation 410 may then involve cleaning patterned flexible substrate 504 following the electrodeposition. FIG. 6 shows an N-type thermoelectric leg 602_{1-P} and a P-type thermoelectric leg 604_{1-P} formed on each pair 510_{1-P} of electrically conductive pads 506_{1-N}, according to one or more embodiments. In one or more embodiments, the aforementioned N-type thermoelectric legs 602_{i—}p and P-type thermoelectric legs 604_{1-P} may be formed on the surface finished patterned flexible substrate 504 (note: in FIG. 6, seed layer 550 is shown as surface finishing over electrically conductive pads 506_{1-N}/leads 512_{1-P}; terminals 520₁₋₂ have been omitted for the sake of clarity) of FIG. 5 through sputter deposition.

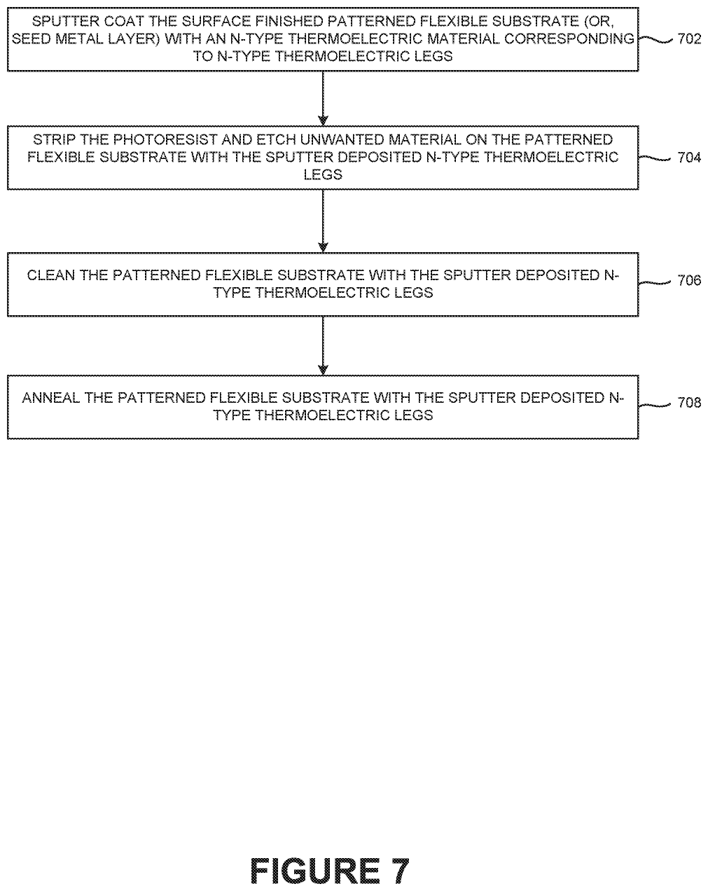

FIG. 7 details the operations involved in sputter deposition of N-type thermoelectric legs 602_{1-P} on the surface finished patterned flexible substrate 504 (or, seed metal layer 550) of FIG. 5, according to one or more embodiments. In one or more embodiments, the aforementioned process may involve a photomask 650 (shown in FIG. 6) on which patterns corresponding/complementary to the N-type thermoelectric legs 602_{1-P} may be generated. In one or more embodiments, a photoresist 670 (shown in FIG. 6) may be applied on the surface finished patterned flexible substrate 504, and photomask 650 placed thereon. In one or more embodiments, operation 702 may involve sputter coating (e.g., through magnetron sputtering) of the surface finished patterned flexible substrate 504 (or, seed metal layer 550) with an N-type thermoelectric material corresponding to N-type thermoelectric legs 602_{1-P}, aided by the use of photomask 650. The photoresist 670/photomask 650 functions are well understood to one skilled in the art; detailed discussion associated therewith has been skipped for the sake of convenience and brevity.

In one or more embodiments, operation 704 may involve stripping (e.g., using solvents such as dimethyl sulfoxide or alkaline solutions) of photoresist 670 and etching of unwanted material on patterned flexible substrate 504 with sputter deposited N-type thermoelectric legs 602_{1-P}. In one or more embodiments, operation 706 may involve cleaning the patterned flexible substrate 504 with the sputter deposited N-type thermoelectric legs 602_{1-P}; the cleaning process may be similar to the discussion with regard to FIG. 4.

In one or more embodiments, operation 708 may then involve annealing the patterned flexible substrate 504 with the sputter deposited N-type thermoelectric legs 602_{1-P}; the annealing process may be conducted (e.g., in air or vacuum) at 175° C. for 4 hours. In one or more embodiments, the annealing process may remove internal stresses and may contribute stability of the sputter deposited N-type thermoelectric legs 602_{1-P}. In one or more embodiments, a dimensional thickness of the sputter deposited N-type thermoelectric legs 602_{1-P} may be less than or equal to 25 μm.

It should be noted that P-type thermoelectric legs 604_{1-P} may also be sputter deposited on the surface finished pattern flexible substrate 504. The operations associated therewith are analogous to those related to the sputter deposition of N-type thermoelectric legs 602_{1-P}. Obviously, photomask 650 may have patterns corresponding/complementary to the P-type thermoelectric legs 604_{1-P} generated thereon. Detailed discussion associated with the sputter deposition of P-type thermoelectric legs 604_{1-P} has been skipped for the sake of convenience; it should be noted that a dimensional thickness of the sputter deposited P-type thermoelectric legs 604_{1-P} may also be less than or equal to 25 μm.

It should be noted that the sputter deposition of P-type thermoelectric legs 604_{1-P} on the surface finished patterned flexible substrate 504 may be performed after the sputter deposition of N-type thermoelectric legs 602_{1-P} thereon or vice versa. Also, it should be noted that various feasible forms of sputter deposition are within the scope of the exemplary embodiments discussed herein. In one or more embodiments, the sputter deposited P-type thermoelectric legs 604_{1-P} and/or N-type thermoelectric legs 602_{1-P} may include a material chosen from one of: Bismuth Telluride (Bi₂Te₃), Bismuth Selenide (Bi₂Se₃), Antimony Telluride (Sb₂Te₃), Lead Telluride (PbTe), Silicides, Skutterudites and Oxides.

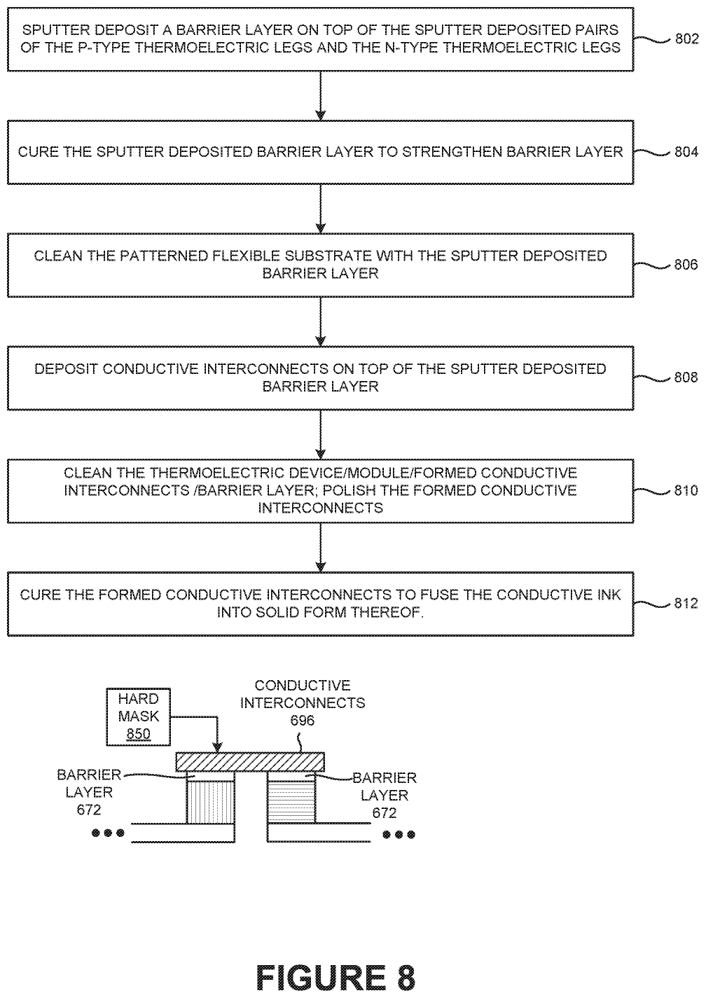

FIG. 8 details operations involved in deposition of a barrier layer 672 (refer to FIG. 6) on top of the sputter deposited pairs of P-type thermoelectric legs 604_{1-P} and N-type thermoelectric legs 602_{1-P} and forming conductive interconnects 696 on top of barrier layer 672, according to one or more embodiments.

In one or more embodiments, operation 802 may involve sputter depositing barrier layer 672 (e.g., film) on top of the sputter deposited pairs of the P-type thermoelectric legs 604_{1-P} and the N-type thermoelectric leg 602_{1-P} discussed above. In one or more embodiments, barrier layer 672 may be electrically conductive and may have a higher melting temperature than the thermoelectric material forming the P-type thermoelectric legs 604_{1-P} and the N-type thermoelectric legs 602_{1-P}. In one or more embodiments, barrier layer 672 may prevent corruption (e.g., through diffusion, sublimation) of one layer (e.g., the thermoelectric layer including the P-type thermoelectric legs 604_{1-P} and the N-type thermoelectric legs 602_{1-P}) by another layer. An example material employed as barrier layer 672 may include but is not limited to Cr, Ni or Au. Further, in one or more embodiments, barrier layer 672 may further aid metallization contact therewith (e.g., with conductive interconnects 696).

In one or more embodiments, a dimensional thickness of barrier layer 672 may be less than or equal to 5 μm. It is obvious that another photomask (not shown) analogous to photomask 650 may be employed to aid the patterned sputter deposition of barrier layer 672; details thereof have been skipped for the sake of convenience and clarity. In one or more embodiments, operation 804 may involve may involve curing barrier layer 672 at 175° C. for 4 hours to strengthen barrier layer 672. In one or more embodiments, operation 806 may then involve cleaning patterned flexible substrate 504 with barrier layer 672.

In one or more embodiments, operation 808 may involve depositing conductive interconnects 696 on top of barrier layer 672. In one example embodiment, the aforementioned deposition may be accomplished by screen printing silver (Ag) ink or other conductive forms of ink on barrier layer 672. Other forms of conductive interconnects 696 based on conductive paste(s) are within the scope of the exemplary embodiments discussed herein. As shown in FIG. 8, a hard mask 850 may be employed to assist the selective application of conductive interconnects 696 based on screen printing of Ag ink. In one example embodiment, hard mask 850 may be a stencil.

In one or more embodiments, the screen printing of Ag ink may contribute to the continued flexibility of the thermoelectric device/module and low contact resistance. In one or more embodiments, operation 810 may involve cleaning (e.g., using one or more of the processes discussed above) the thermoelectric device/module/formed conductive interconnects 696/barrier layer 672 and polishing conductive interconnects 696. In one example embodiment, the polishing may be followed by another cleaning process. In one or more embodiments, operation 812 may then involve curing conductive interconnects 696 at 175° C. for 4 hours to fuse the conductive ink into solid form thereof. In one or more embodiments, conductive interconnects 696 may have a dimensional thickness less than or equal to 25 μm.

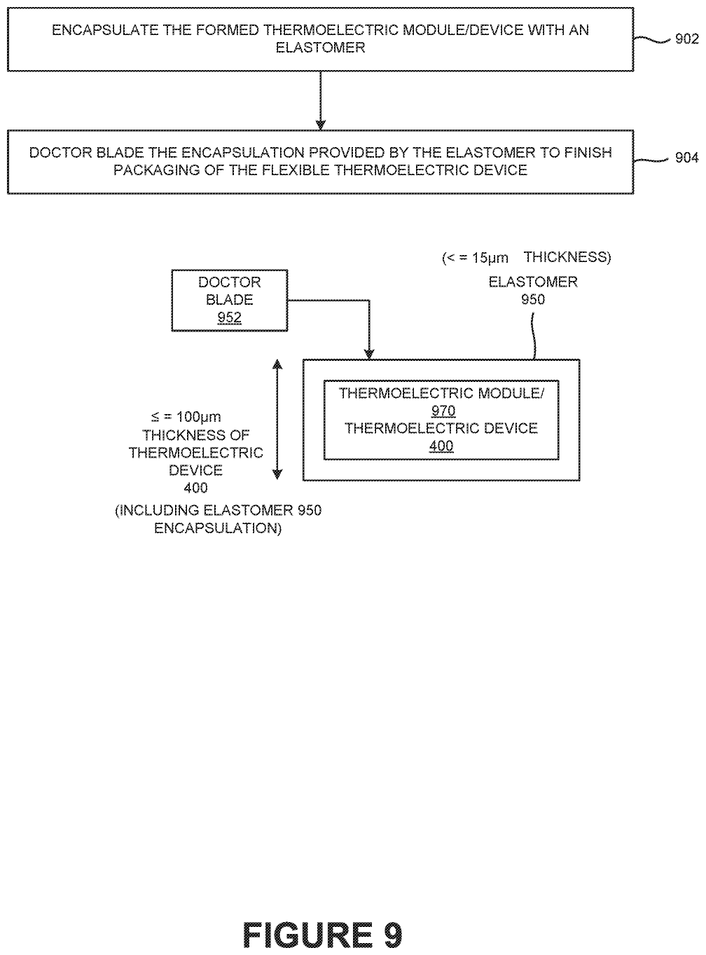

FIG. 9 details the operations involved in encapsulating the thermoelectric device (e.g., thermoelectric module 970)/module discussed above, according to one or more embodiments. In one or more embodiments, operation 902 may involve encapsulating the formed thermoelectric module (e.g., thermoelectric module 970)/device (with barrier layer 672 and conductive interconnects 696) with an elastomer 950 to render flexibility thereto. In one or more embodiments, as shown in FIG. 9, the encapsulation provided by elastomer 950 may have a dimensional thickness of less than or equal to 15 μm. In one or more embodiments, operation 904 may involve doctor blading (e.g., using doctor blade 952) the encapsulation provided by elastomer 950 to finish packaging of the flexible thermoelectric device/module discussed above.

In one or more embodiments, the doctor blading may involve controlling precision of a thickness of the encapsulation provided by elastomer 950 through doctor blade 952. In one example embodiment, elastomer 950 may be silicone. Here, said silicone may be loaded with nano-size aluminum oxide (Al₂O₃) powder to enhance thermal conductivity thereof to aid heat transfer across the thermoelectric module.

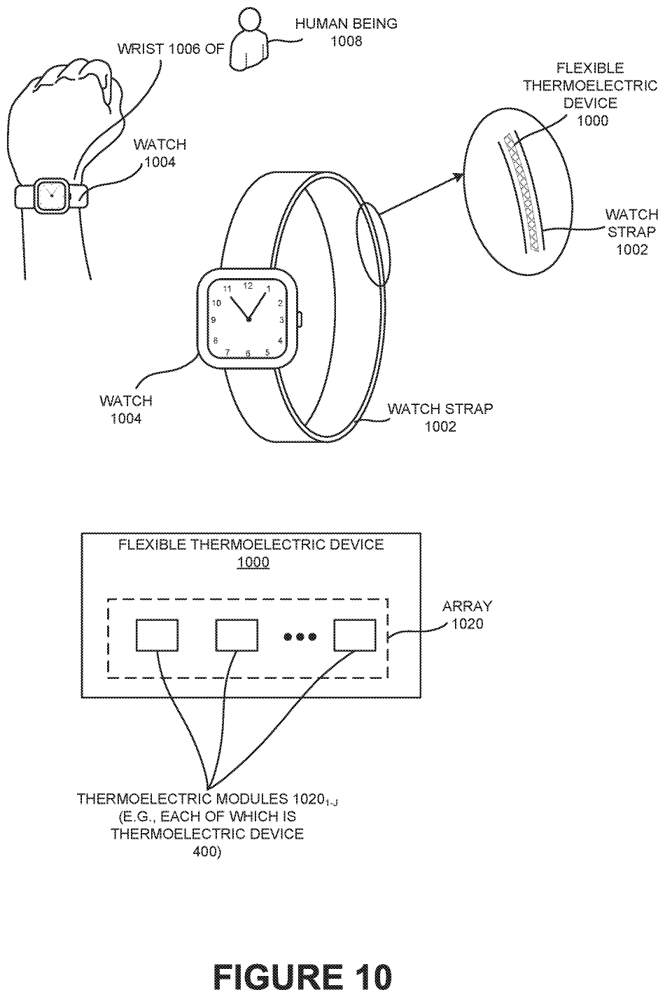

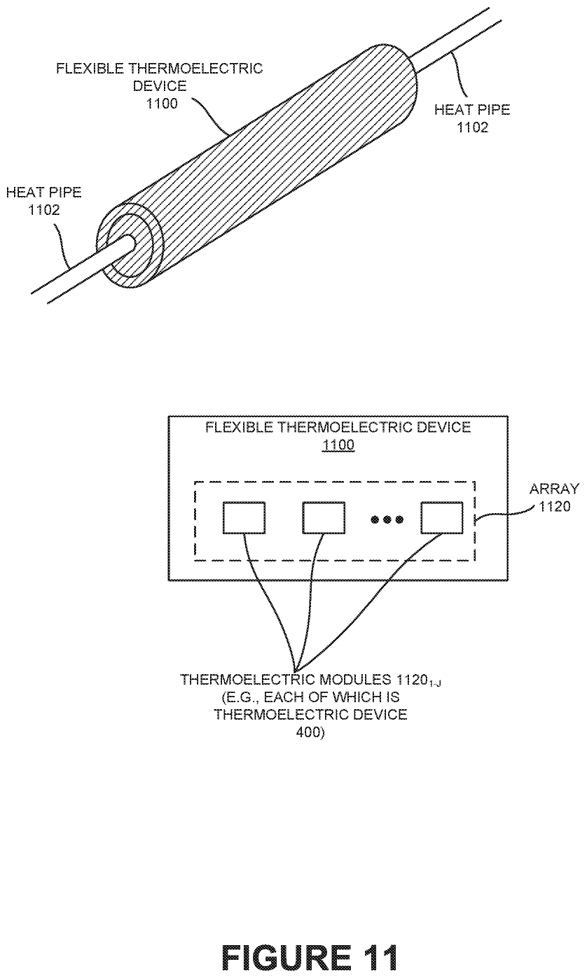

In one or more embodiments, as seen above, all operations involved in fabricating the thermoelectric device/module (e.g., thermoelectric device 400) render said thermoelectric device/module flexible. FIG. 10 shows a flexible thermoelectric device 1000 discussed herein embedded within a watch strap 1002 of a watch 1004 completely wrappable around a wrist 1006 of a human being 1008; flexible thermoelectric device 1000 may include an array 1020 of thermoelectric modules 1020_{1-J} (e.g., each of which is thermoelectric device 400) discussed herein. In one example embodiment, flexible thermoelectric device 1000 may serve to augment or substitute power derivation from a battery of watch 1004. FIG. 11 shows a flexible thermoelectric device 1100 discussed herein wrapped around a heat pipe 1102; again, flexible thermoelectric device 1100 may include an array 1120 of thermoelectric modules 1120_{1-J} (e.g., each of which is thermoelectric device 400) discussed herein. In one example embodiment, flexible thermoelectric device 1100 may be employed to derive thermoelectric power (e.g., through array 1120) from waste heat from heat pipe 1102.

It should be noted that although photomask 650 is discussed above with regard to deposition of N-type thermoelectric legs 602_{1-P} and a P-type thermoelectric legs 604_{1-P}, the aforementioned deposition may, in one or more other embodiments, involve a hard mask 690, as shown in FIG. 6. Further, it should be noted that flexible thermoelectric device 400/1000/1100 may be fabricated/manufactured such that the aforementioned device is completely wrappable and bendable around a system element (e.g., watch 1004, heat pipe 1102) that requires said flexible thermoelectric device 400/1000/1100 to perform a thermoelectric power generation function using the system element.

The abovementioned flexibility of thermoelectric device 400/1000/1100 may be enabled through proper selection of flexible substrates (e.g., substrate 350) and manufacturing techniques/processes that aid therein, as discussed above. Further, flexible thermoelectric device 1000/1100 may be bendable 360° such that the entire device may completely wrap around the system element discussed above. Still further, in one or more embodiments, an entire dimensional thickness of the flexible thermoelectric module (e.g., flexible thermoelectric device 400) in a packaged form may be less than or equal to 100 μm, as shown in FIG. 9.

Last but not the least, as the dimensions involved herein are restricted to less than or equal to 100 μm, the flexible thermoelectric device/module discussed above may be regarded as being thin-film based (e.g., including processes involved in fabrication thereof).

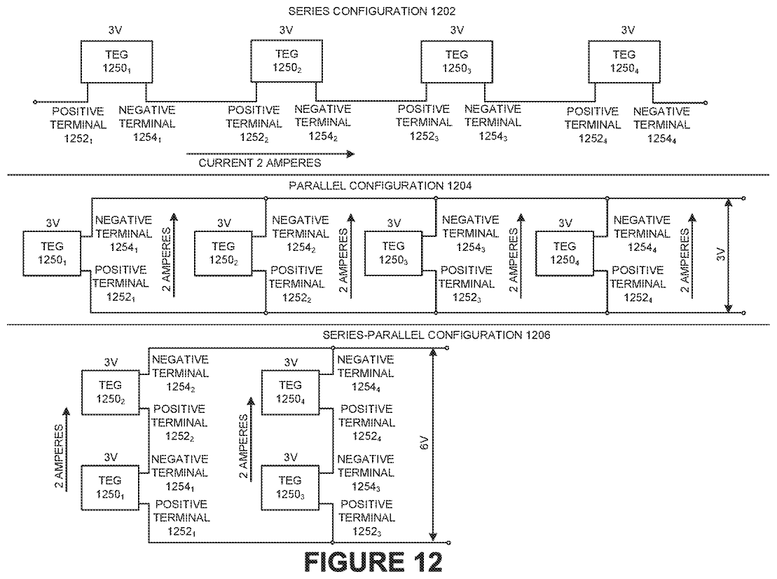

FIG. 12 shows example wiring configurations of an example set of four equivalent thermoelectric generators (TEGs) 1250₁₋₄ including a series configuration 1202, a parallel configuration 1204 and a series-parallel configuration 1206. TEGs are known to one skilled in the art. Detailed discussion associated therewith has been skipped for the sake of convenience and brevity. Each TEG 1250₁₋₄ may be assumed to produce a hypothetical 3 volts and 2 amperes. In series configuration 1202, a negative terminal 1254₁ of the first TEG 1250₁ may be electrically connected to a positive terminal 1252₂ of the second TEG 1250₂, a negative terminal 1254₂ of the second TEG 1250₂ may be electrically connected to a positive terminal 1252₃ of the third TEG 1250₃, and a negative terminal 1254₃ of the third TEG 12503 may be electrically connected to a positive terminal 1252₄ of the fourth TEG 1250₄. The voltage between a positive terminal 1252₁ of the first TEG 1250₁ and a negative terminal 1254₄ of the fourth TEG 1250₄ may be the sum of voltages across terminals of each TEG 1250₁₋₄, i.e., 3+3+3+3 =12 volts, while the current flowing in series configuration 1202 may be the same for each TEG 1250₁₋₄, i.e., 2 amperes. Therefore, the power output of series configuration 1202 may be 24 watts (W).

In parallel configuration 1204, positive terminals 1252₁₋₄ of TEGs 1250₁₋₄ may be electrically connected together and negative terminals 1254₁₋₄ of TEGs 1250₁₋₄ may be electrically connected together. The voltage between the electrically connected positive terminals 1252₁₋₄ and the electrically connected negative terminals 1254₁₋₄ in parallel configuration 1204 may be the same 3 volts, while the currents add up to 2+2+2+2=8 amperes. Therefore, the power output of parallel configuration 1204 may, again, be 24 W.

In series-parallel configuration 1206, which is a combination of series configuration 1202 and parallel configuration 1204, the negative terminal 1254₁ of the first TEG 1250₁ may be electrically connected to the positive terminal 1252₂ of the second TEG 1250₂. Similarly, the negative terminal 1254₃ of the third TEG 1250₃ may be electrically connected to the positive terminal 1252₄ of the fourth TEG 1250₄. In addition, the positive terminal 1252₁ and the positive terminal 1252₃ of the first TEG 1250₁ and the third TEG 1250₃ respectively may be electrically connected together and the negative terminal 1254₂ and the negative terminal 1254₄ of the second TEG 1250₂ and the fourth TEG 1250₄ respectively may be electrically connected together. Here, the current through each of the first TEG 1250₁-second TEG 1250₂ branch and the third TEG 1250₃-fourth TEG 1250₄ branch may be 2 amperes. These currents may add up to 4 amperes. The voltage across each of the aforementioned branches may be 3+3=6 volts. Thus, the power output of series-parallel configuration 1206 may, again, be 24 W.

The current state-of-the-art TEGs (e.g., TEGs 1250₁₋₄) may be unit devices that may be electrically connected either in series or in parallel. Typical bulk TEG modules may be limited in size due to rigidity of substrates and longer dimensions of thermoelectric legs thereof. Thus, the aforementioned bulk TEG modules may almost always be standalone devices where N and P thermoelectric elements/legs are connected in series or in parallel on rigid substrates (e.g., Aluminum Oxide (Al₂O₃)). Adding cells/pairs/series of N and P legs in a bulk TEG module may increase the series resistance thereof.

As the series resistance goes up, an output current of the bulk TEG module drops. At low temperature differences between a hot end and a cold end of the bulk TEG module, there may not be enough of an output voltage, which, coupled with the negligible current because of high module resistance, causes the bulk TEG module to not work. Even though thermoelectric modules may be designed taking the aforementioned issues into account, no bulk TEG module more than a couple of inches in dimensional length may typically be available in the market. This may mainly be due to process restrictions and electrical output limitations at low temperature differences.

In one or more embodiments, manufacturing a large (e.g., 1 square meter) area thermoelectric module may require organization of various thermoelectric cells/sets/pairs of N legs and P legs into clusters, and subsequent grouping of the aforementioned clusters into series and parallel design configurations (to be discussed below) to manage overall resistance, and, thereby, output current.

FIG. 3 shows a single thermoelectric module (e.g., thermoelectric device component 300) where each set 302_{1-M} of N leg 304_{1-M} and P leg 306_{1-M} is electrically coupled to another set 302_{1-M} in series, according to one or more embodiments. As seen therein, the series configuration may involve an N leg 304_{1-M} of one set 302_{1-M} being electrically connected to a P leg 306_{1-M} of a neighboring set 302_{1-M}. The P leg 306_{1-M} of the one set 302_{1-M} may be electrically connected to an N leg 304_{1-M} of a previous set 302_{1-M}. It is also possible to envision a configuration where an N leg 304_{1-M} of one set 302_{1-J\4} may be electrically connected to an N leg 304_{1-M} of a neighboring set 302_{1-M}. Here, the P leg 306_{1-M} of the one set 302_{1-M} may be electrically connected to a P leg 306_{1-M} of a previous set 302_{1-M}. The aforementioned N-N and P-P thermoelectric leg electrical connections between sets 302_{1-M} may be a parallel configuration of thermoelectric legs within the single thermoelectric module.

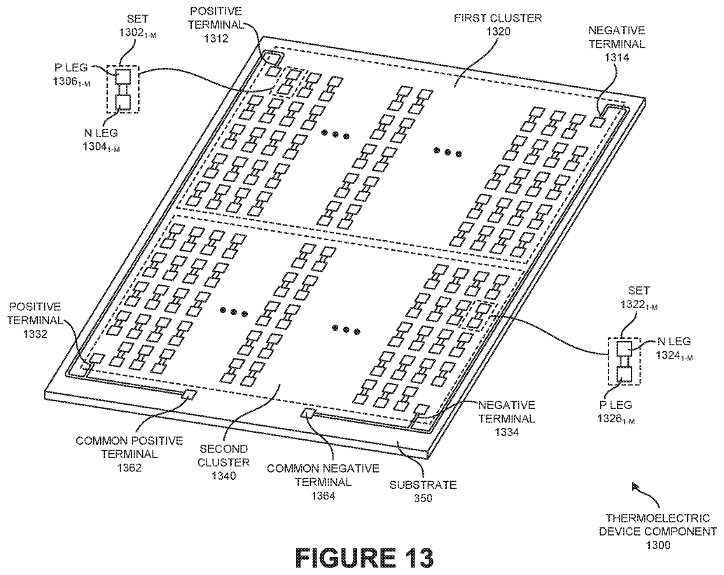

FIG. 13 shows a two cluster series-parallel configuration of a thermoelectric device component 1300 (analogous to thermoelectric device component 300), according to one or more embodiments. In one or more embodiments, thermoelectric device component 1300 may include a first cluster 1320 in which each set 1302_{1-M} (of sets 1302_{1-M}) of N leg 1304_{1-M} and P leg 1306_{1-M} may be electrically connected to another set 1302_{1-M} in series, and a second cluster 1340 in which each set 1322_{1-M} (of sets 1322_{1-M}) of N leg 1324_{1-M} and P leg 1326_{1-M} may be electrically connected to another set 1322_{1-M} in series. It is obvious that set 1302_{1-M} and set 1322_{1-M} may be analogous to set 302_{1-M} of FIG. 3, and that the thermoelectric legs of sets 1302_{1-M} and sets 1322_{1-M} may be deposited on pairs 510_{1-P} of electrically conductive pads 506_{1-N} (see FIG. 5). All concepts associated with FIGS. 1-11 are applicable to embodiments associated with FIG. 12 onward.

It should be noted that first cluster 1320 and second cluster 1340 may be distributed across substrate 350 (or, patterned flexible substrate 504). Now, in one or more embodiments, first cluster 1320 may be electrically connected to second cluster 1340 in parallel, as shown in FIG. 13. In other words, a positive terminal 1312 of first cluster 1320 may be electrically connected to a positive terminal 1332 of second cluster 1340 to realize a common positive terminal 1362 and a negative terminal 1314 of first cluster 1320 may be electrically connected to a negative terminal 1334 of second cluster 1340 to realize a common negative terminal 1364. In one or more embodiments, an output voltage may be measurable across common positive terminal 1362 and common negative terminal 1364, thereby rendering utilization thereof possible.

It is possible to envision first cluster 1320 and second cluster 1340 where sets (1302_{1-M}, 1322_{1-M}) of legs are electrically connected to one another in parallel (N-N and P-P, as discussed above) instead of series. In one or more other embodiments, first cluster 1320 and second cluster 1340 may be electrically coupled to one another in series instead of in parallel as in FIG. 13. Here, negative terminal 1314 of first cluster 1320 may be electrically connected to positive terminal 1332 of second cluster 1320, and an output voltage may be measurable across positive terminal 1312 of first cluster 1320 and negative terminal 1334 of second cluster 1320. In one or more embodiments, the series or parallel electrical connections may be dictated by output requirements (e.g., overall resistance, output current) corresponding to temperature differences between a hot end and a cold end of thermoelectric device component 1300. The aforementioned variations are within the scope of the exemplary embodiments discussed herein.

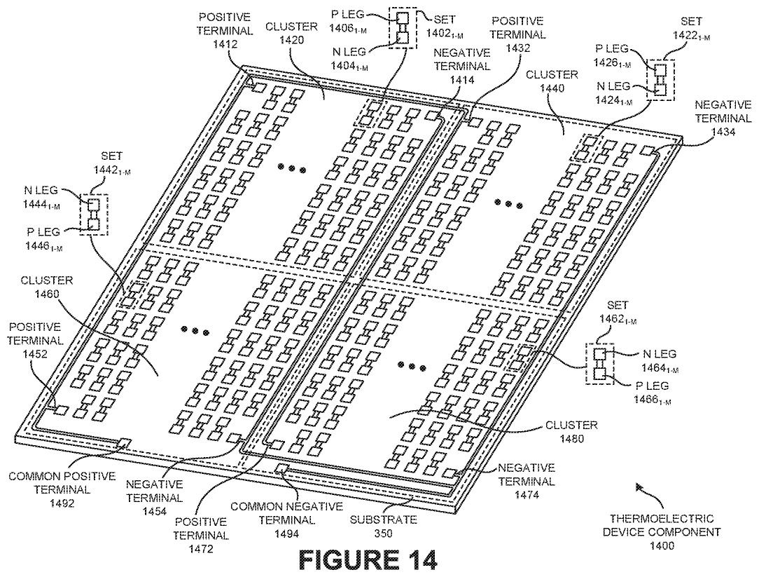

FIG. 14 shows a four cluster series-parallel configuration of a thermoelectric device component 1400 (analogous to thermoelectric device component 300), according to one or more embodiments. Again, each of the four clusters (1420, 1440, 1460 and 1480) may include sets (1402_{1-M}, 1422_{1-M}, 1442_{1-M} and 1462_{1-M}) of N legs (1404_{1-M}, 1424_{1-M}, 1444_{1-M} and 1464_{1-M}) and P legs (1406_{1-M}, 1426_{1-M}, 1446_{1-M} and 1466_{1-M}) in which one set (1402_{1-M}, 1422_{1-M}, 1442_{1-M} and 1462_{1-M}) may be electrically connected to another set (1402_{1-M}, 1422_{1-M}, 1442_{1-M} and 1462_{1-M}) in series. Again, it is obvious that each of the sets (1402_{1-M}, 1422_{1-M}, 1442_{1-M} and 1462_{1-M}) may be analogous to set 302_{1-M} of FIG. 3, and that the thermoelectric legs of the aforementioned sets (1402_{1-M}, 1422_{1-M}, 1442_{1-M} and 1462_{1-M}) may be deposited on pairs 510_{1-P} of electrically conductive pads 506_{1-N} (see FIG. 5).

Again, it should be noted that each of the four clusters (1420, 1440, 1460 and 1480) may be distributed across substrate 350 (or, patterned flexible substrate 504). Again, in one or more embodiments, each cluster (1420, 1440, 1460 and 1480) may be electrically connected to one another in parallel, as shown in FIG. 14. In other words, positive terminals (1412, 1432, 1452 and 1472) of the clusters (1420, 1440, 1460 and 1480) may be electrically connected to one another to realize a common positive terminal 1492 and negative terminals (1414, 1434, 1454 and 1474) of the clusters (1420, 1440, 1460 and 1480) may be electrically connected to one another to realize a common negative terminal 1494. In one or more embodiments, an output voltage may be measurable across common positive terminal 1492 and common negative terminal 1494, thereby rendering utilization thereof possible.

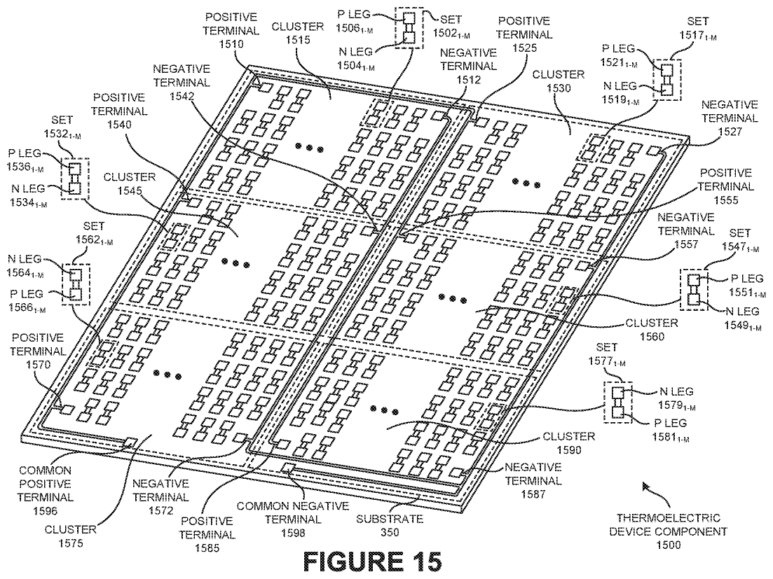

FIG. 15 shows a six cluster series-parallel configuration of a thermoelectric device component 1500 (analogous to thermoelectric device component 300), according to one or more embodiments. Yet again, each of the six clusters (1515, 1530, 1545, 1560, 1575 and 1590) may include sets (1502_{1-M}, 1517_{1-M}, 1532_{1-M}, 1547_{1-M}, 1562_{1-M} and 1577_{1-M}) of N legs (1504_{1-M}, 1519_{1-M}, 1534_{1-M}, 1549_{1-M}, 1564_{1-M} and 1579_{1-M}) and P legs (1506_{1-M}, 1521_{1-M}, 1536_{1-M}, 1551_{1-M}, 1566_{1-M} and 1581_{1-M}) in which one set (1502_{1-M}, 1517_{1-M}, 1532_{1-M}, 1547_{1-M}, 1562_{1-M} and 1577_{1-M}) may be electrically connected to another set (1502_{1-M}, 1517_{1-M}, 1532_{1-M}, 1547_{1-M}, 1562_{1-M} and 1577_{1-M}) in series. Again, it is obvious that each of the sets (1502_{1-M}, 1517_{1-M}, 1532_{1-M}, 1547_{1-M}, 1562_{1-M} and 1577_{1-M}) may be analogous to set 302_{1-M} of FIG. 3, and that the thermoelectric legs of the aforementioned sets (1502_{1-M}, 1517_{1-M}, 1532_{1-M}, 1547_{1-M}, 1562_{1-M} and 1577_{1-M}) may be deposited on pairs 510_{1-P} of electrically conductive pads 506_{1-N} (see FIG. 5).

Again, it should be noted that each of the six clusters (1515, 1530, 1545, 1560, 1575 and 1590) may be distributed across substrate 350 (or, patterned flexible substrate 504). Again, in one or more embodiments, each cluster (1515, 1530, 1545, 1560, 1575 and 1590) may be electrically connected to one another in parallel, as shown in FIG. 15. In other words, positive terminals (1510, 1525, 1540, 1555, 1570 and 1585) of the clusters (1515, 1530, 1545, 1560, 1575 and 1590) may be electrically connected to one another to realize a common positive terminal 1596 and negative terminals (1512, 1527, 1542, 1557, 1572 and 1587) of the clusters (1515, 1530, 1545, 1560, 1575 and 1590) may be electrically connected to one another to realize a common negative terminal 1598. In one or more embodiments, an output voltage may be measurable across common positive terminal 1596 and common negative terminal 1598, thereby rendering utilization thereof possible.

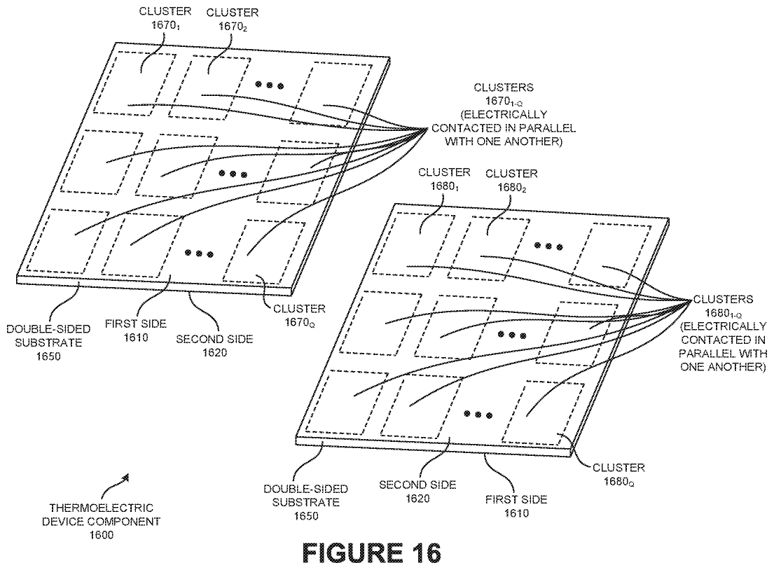

FIG. 16 shows a thermoelectric device component 1600, according to one or more embodiments. Here, in one or more embodiments, both sides (e.g., a first side 1610 and a second side 1620) of a double-sided substrate 1650 (analogous to substrate 350, or, flexible patterned substrate 504) may include clusters (e.g., clusters 1670_{1-Q}, clusters 1680_{1-Q}) of thermoelectric legs in series that are electrically connected in parallel to one another. In other words, clusters 1670_{1-Q} may be coupled in parallel to one another on first side 1610 and clusters 1680_{1-Q} may be coupled in parallel to one another on second side 1620. In one or more embodiments, the aforementioned two-sidedness may involve deposition of thermoelectric legs on electrically conductive pads discussed above with reference to FIGS. 1-11 on both sides of double-sided substrate 1650.

In one or more embodiments, utilization of both sides (or, both surfaces) of double-sided substrate 1650 may approximately double performance by enabling two thermoelectric device sub-components (one on either side) of thermoelectric device component 1600 utilize a given temperature difference between the sides (e.g., first side 1610 and second side 1620) instead of merely one. In one or more embodiments, as two sets of clusters of thermoelectric legs (one on top of first side 1610 and another on top of second side 1620) provide for double the effective thermoelectric thickness compared to merely one set, the performance of a thermoelectric device incorporating thermoelectric device component 1600 may approximately be doubled for a given temperature difference between the sides.

Again, it is possible to envision clusters of the thermoelectric device components 1300-1600 where sets of legs are electrically connected to one another in parallel instead of series. Also, it is possible to envision one cluster of a thermoelectric device component 1300-1600 being electrically connected to another cluster thereof in series instead of in parallel. Again, in one or more embodiments, the series or parallel electrical connections may be dictated by output requirements (e.g., overall resistance, output current) corresponding to temperature differences between a hot end and a cold end of thermoelectric device component 1300-1600. The aforementioned variations are within the scope of the exemplary embodiments discussed herein. Parallel electrical connections between sets of thermoelectric legs within a cluster and series electrical connections between a cluster are obvious in view of the connections illustrated in FIGS. 13-16. Therefore, explicit illustration thereof has been skipped for the sake of convenience, clarity and brevity.

It is clear that the embodiments discussed with regard to FIGS. 13-16 are generalizable to any number of clusters (e.g., Q clusters). Within a cluster, there may be any number of sets of thermoelectric legs (e.g., 2 to any large number). The number of sets of thermoelectric legs may vary across clusters on a substrate (e.g., substrate 350). In one or more embodiments, the clusterization discussed above in thermoelectric device components 1300-1600 may lead to increased output (e.g., output current) compared to a bulk TEG module where clusterization is limited. In one or more embodiments, the clusterization may also allow for increased power densities within an area of substrate 350. Moreover, in one or more embodiments, all advantages including advantages of flexibility, size and scalability discussed above with regard to FIGS. 1-11 may also be applicable to the embodiments of FIGS. 13-16. These advantages of flexibility, size and scalability, in addition to the processes involved, may enable large-scale clusterization and inclusion of a large number of sets of thermoelectric legs within thermoelectric device component 1300-1600.

Additionally, it should be noted that the number of clusters and the number of sets of thermoelectric legs within a cluster may vary across two surfaces/sides of double-sided substrate 1650. Also, in one or more embodiments, one cluster may include a different thermoelectric material compared to another cluster on a substrate 350/double-sided substrate 1650. Further, it should be noted that pairs 510_{1-P} corresponding to the thermoelectric legs of each individual cluster may be deposited (e.g., simultaneously) using the processes discussed above. All reasonable variations are within the scope of the exemplary embodiments discussed herein.

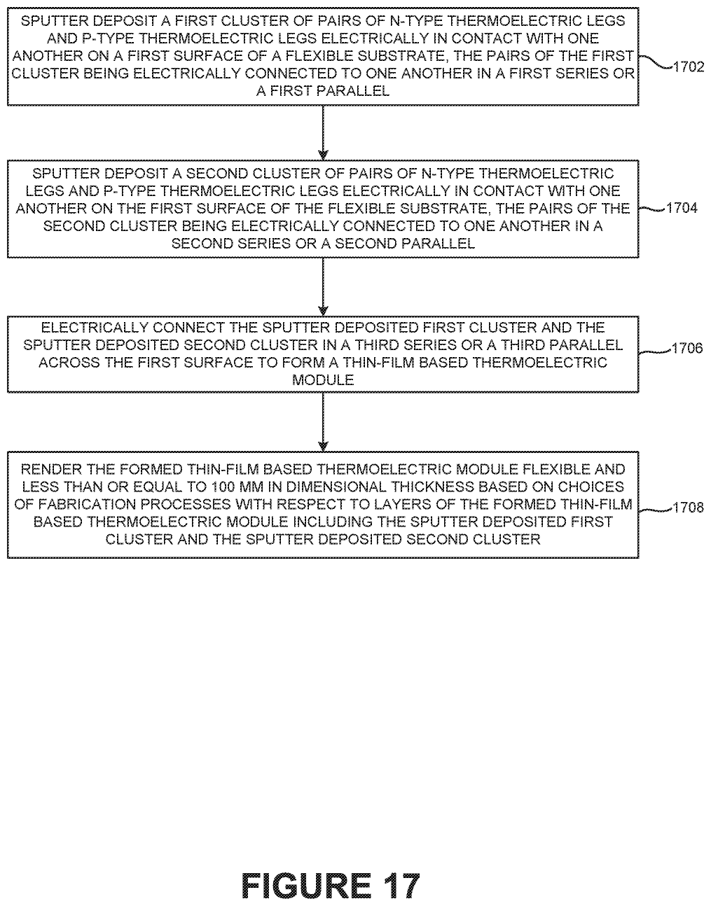

FIG. 17 shows a process flow diagram detailing the operations involved in realizing a series-parallel cluster configuration of a thin-film based thermoelectric module (e.g., thermoelectric device components 1300-1600), according to one or more embodiments. In one or more embodiments, operation 1702 may involve sputter depositing a first cluster (e.g., first cluster 1320, cluster 1420, cluster 1515, cluster 1670₁) of pairs of N-type thermoelectric legs and P-type thermoelectric legs electrically in contact with one another on a first surface (e.g., first side 1610) of a flexible substrate (e.g., flexible substrate 350). In one or more embodiments, the flexible substrate may be Al foil, a sheet of paper, polytetrafluoroethylene, polyimide, plastic, a single-sided Cu clad laminate sheet, or a double-sided Cu clad laminate sheet. In one or more embodiments, the flexible substrate may have a dimensional thickness less than or equal to 25 μm, and the pairs of the first cluster may be electrically connected to one another in a first series or a first parallel.

In one or more embodiments, operation 1704 may involve sputter depositing a second cluster (e.g., second cluster 1340, cluster 1440, cluster 1530, cluster 1670₂) of pairs of N-type thermoelectric legs and P-type thermoelectric legs electrically in contact with one another on the first surface of the flexible substrate, with the pairs of the second cluster being electrically connected to one another in a second series or a second parallel. In one or more embodiments, operation 1706 may involve electrically connecting the sputter deposited first cluster and the sputter deposited second cluster in a third series or a third parallel across the first surface to form a thin-film based thermoelectric module (e.g., thermoelectric device component 1300-1600).

In one or more embodiments, operation 1708 may then involve rendering the formed thin-film based thermoelectric module flexible and less than or equal to 100 μm in dimensional thickness based on choices of fabrication processes with respect to layers of the formed thin-film based thermoelectric module including the sputter deposited first cluster and the sputter deposited second cluster. In one or more embodiments, the flexibility may enable the formed thin-film based thermoelectric module to be completely wrappable and bendable around a system element (e.g., heat element 1102) from which the formed thin-film based thermoelectric module is configured to derive thermoelectric power, and a layer of the formed thin-film based thermoelectric module including the sputter deposited N-type thermoelectric legs and the P-type thermoelectric legs of the pairs of the first cluster and the pairs of the second cluster may have a dimensional thickness less than or equal to 25 μm.

Although the present embodiments have been described with reference to specific example embodiments, it will be evident that various modifications and changes may be made to these embodiments without departing from the broader spirit and scope of the various embodiments. Accordingly, the specification and drawings are to be regarded in an illustrative rather than a restrictive sense.

What is claimed is:

1. A method comprising:
sputter depositing a first cluster of pairs of N-type thermoelectric legs and P-type thermoelectric legs electrically in contact with one another on a first surface of a flexible substrate, the flexible substrate being one of: aluminum (Al) foil, a sheet of paper, polytetrafluoroethylene, polyimide, plastic, a single-sided copper (Cu) clad laminate sheet, and a double-sided Cu clad laminate sheet, the flexible substrate having a dimensional thickness less than or equal to 25 μm, and the pairs of the first cluster being electrically connected to one another in one of: a first series and a first parallel;
sputter depositing a second cluster of pairs of N-type thermoelectric legs and P-type thermoelectric legs electrically in contact with one another on the first surface of the flexible substrate, the pairs of the second cluster being electrically connected to one another in one of: a second series and a second parallel;
electrically connecting the sputter deposited first cluster and the sputter deposited second cluster in one of: a third series and a third parallel across the first surface to form a thin-film based thermoelectric module; and
rendering the formed thin-film based thermoelectric module flexible and less than or equal to 100 μm in dimensional thickness based on choices of fabrication processes with respect to layers of the formed thin-film based thermoelectric module including the sputter deposited first cluster and the sputter deposited second cluster, the flexibility enabling the formed thin-film based thermoelectric module to be completely wrappable and bendable around a system element from which the formed thin-film based thermoelectric module is configured to derive thermoelectric power, and a layer of the formed thin-film based thermoelectric module including the sputter deposited N-type thermoelectric legs and the P-type thermoelectric legs of the pairs of the first cluster and the pairs of the second cluster having a dimensional thickness less than or equal to 25 μm.

2. The method of claim 1, comprising:
the third parallel corresponding to electrically connecting a first positive terminal of the first cluster and a second positive terminal of the second cluster together as a common positive terminal and electrically connecting a first negative terminal of the first cluster and a second negative terminal of the second cluster together as a common negative terminal; and
utilizing the common positive terminal and the common negative terminal as output terminals of the formed thin-film based thermoelectric module.

3. The method of claim 1, further comprising:
sputter depositing a third cluster of pairs of N-type thermoelectric legs and P-type thermoelectric legs electrically in contact with one another on a second surface of the flexible substrate, the pairs of the third cluster being electrically connected to one another in one of: a fourth series and a fourth parallel;
sputter depositing a fourth cluster of pairs of N-type thermoelectric legs and P-type thermoelectric legs electrically in contact with one another on the second surface of the flexible substrate, the pairs of the fourth cluster being electrically connected to one another in one of: a fifth series and a fifth parallel; and
electrically connecting the sputter deposited third cluster and the sputter deposited fourth cluster in one of: a sixth series and a sixth parallel to form a double-sided configuration of the formed thin-film based thermoelectric module.

4. The method of claim 1, further comprising:
printing and etching a design pattern of metal onto the first surface of the flexible substrate to form electrically conductive pads, leads and terminals on the flexible substrate corresponding to each of the first cluster and the second cluster, the formed electrically conductive pads, the leads and the terminals having a dimensional thickness less than or equal to 18 μm;
additionally electrodepositing a seed metal layer comprising at least one of: Chromium (Cr), Nickel (Ni) and Gold (Au) directly on top of the formed electrically conductive pads, the leads and the terminals on the flexible substrate following the printing and etching thereof, the seed metal layer having a dimensional thickness less than or equal to 5 μm; and
sputter depositing the pairs of the N-type thermoelectric legs and the P-type thermoelectric legs of the each of the first cluster and the second cluster directly on top of the electrodeposited seed metal layer.

5. The method of claim 1, further comprising encapsulating the formed thin-film based thermoelectric module with an elastomer to render the flexibility thereto, the elastomer providing an encapsulation having a dimensional thickness less than or equal to 15 μm.

6. The method of claim 5, comprising the elastomer being silicone.

7. The method of claim 6, further comprising:
loading the silicone with nano-size aluminum oxide (Al₂O₃) powder to enhance thermal conductivity thereof to aid heat transfer across the formed thin-film based thermoelectric module.

8. A method comprising:
sputter depositing a first cluster of pairs of N-type thermoelectric legs and P-type thermoelectric legs electrically in contact with one another on a first surface of a flexible substrate, the flexible substrate being one of: Al foil, a sheet of paper, polytetrafluoroethylene, polyimide, plastic, a single-sided Cu clad laminate sheet, and a double-sided Cu clad laminate sheet, the flexible substrate having a dimensional thickness less than or equal to 25 μm, and the pairs of the first cluster being electrically connected to one another in one of: a first series and a first parallel;
sputter depositing a second cluster of pairs of N-type thermoelectric legs and P-type thermoelectric legs electrically in contact with one another on the first surface of the flexible substrate, the pairs of the second cluster being electrically connected to one another in one of: a second series and a second parallel;
electrically connecting the sputter deposited first cluster and the sputter deposited second cluster in one of: a third series and a third parallel across the first surface to form a thin-film based thermoelectric module;
encapsulating the formed thin-film based thermoelectric module with an elastomer to render flexibility thereto, the elastomer providing an encapsulation having a dimensional thickness less than or equal to 15 μm; and
additionally rendering the encapsulated formed thin-film based thermoelectric module flexible and less than or equal to 100 μm in dimensional thickness based on choices of fabrication processes with respect to layers of the encapsulated formed thin-film based thermoelectric module including the sputter deposited first cluster and the sputter deposited second cluster, the additional flexibility enabling the encapsulated formed thin-film based thermoelectric module to be completely wrappable and bendable around a system element from which the encapsulated formed thin-film based thermoelectric module is configured to derive thermoelectric power, and a layer of the encapsulated formed thin-film based thermoelectric module including the sputter deposited N-type thermoelectric legs and the P-type thermoelectric legs of the pairs of the first cluster and the pairs of the second cluster having a dimensional thickness less than or equal to 25 μm.

9. The method of claim 8, comprising:
the third parallel corresponding to electrically connecting a first positive terminal of the first cluster and a second positive terminal of the second cluster together as a common positive terminal and electrically connecting a first negative terminal of the first cluster and a second negative terminal of the second cluster together as a common negative terminal; and
utilizing the common positive terminal and the common negative terminal as output terminals of the formed thin-film based thermoelectric module.

10. The method of claim 8, further comprising:
sputter depositing a third cluster of pairs of N-type thermoelectric legs and P-type thermoelectric legs electrically in contact with one another on a second surface of the flexible substrate, the pairs of the third cluster being electrically connected to one another in one of: a fourth series and a fourth parallel;
sputter depositing a fourth cluster of pairs of N-type thermoelectric legs and P-type thermoelectric legs electrically in contact with one another on the second surface of the flexible substrate, the pairs of the fourth cluster being electrically connected to one another in one of: a fifth series and a fifth parallel; and
electrically connecting the sputter deposited third cluster and the sputter deposited fourth cluster in one of: a sixth series and a sixth parallel to form a double-sided configuration of the formed thin-film based thermoelectric module.

11. The method of claim 8, further comprising:
printing and etching a design pattern of metal onto the first surface of the flexible substrate to form electrically conductive pads, leads and terminals on the flexible substrate corresponding to each of the first cluster and the second cluster, the formed electrically conductive pads, the leads and the terminals having a dimensional thickness less than or equal to 18 μm; and
additionally electrodepositing a seed metal layer comprising at least one of: Cr, Ni and Au directly on top of the formed electrically conductive pads, the leads and the terminals on the flexible substrate following the printing and etching thereof, the seed metal layer having a dimensional thickness less than or equal to 5 μm.

12. The method of claim 11, further comprising:
sputter depositing the pairs of the N-type thermoelectric legs and the P-type thermoelectric legs of the each of the first cluster and the second cluster directly on top of the electrodeposited seed metal layer.

13. The method of claim 8, comprising the elastomer being silicone.

14. The method of claim 13, further comprising:
loading the silicone with nano-size Al₂O₃ powder to enhance thermal conductivity thereof to aid heat transfer across the encapsulated formed thin-film based thermoelectric module.

15. A method comprising:
sputter depositing a first cluster of pairs of N-type thermoelectric legs and P-type thermoelectric legs electrically in contact with one another on each of a first surface and a second surface of a flexible substrate, the flexible substrate being one of: Al foil, a sheet of paper, polytetrafluoroethylene, polyimide, plastic, a single-sided Cu clad laminate sheet, and a double-sided Cu clad laminate sheet, the flexible substrate having a dimensional thickness less than or equal to 25 μm, and the pairs of the first cluster being electrically connected to one another in one of: a first series and a first parallel;
sputter depositing a second cluster of pairs of N-type thermoelectric legs and P-type thermoelectric legs electrically in contact with one another on the each of the first surface and the second surface of the flexible substrate, the pairs of the second cluster being electrically connected to one another in one of: a second series and a second parallel;
electrically connecting the sputter deposited first cluster on the each of the first surface and the second surface and the sputter deposited second cluster on the each of the first surface and the second surface in one of: a third series and a third parallel across the each of the first surface and the second surface to form a thin-film based thermoelectric module; and
rendering the formed thin-film based thermoelectric module flexible and less than or equal to 100 μm in dimensional thickness based on choices of fabrication processes with respect to layers of the formed thin-film based thermoelectric module including the sputter deposited first cluster and the sputter deposited second cluster, the flexibility enabling the formed thin-film based thermoelectric module to be completely wrappable and bendable around a system element from which the formed thin-film based thermoelectric module is configured to derive thermoelectric power, and a layer of the formed thin-film based thermoelectric module including the sputter deposited N-type thermoelectric legs and the P-type thermoelectric legs of the pairs of the first cluster and the pairs of the second cluster having a dimensional thickness less than or equal to 25 μm.

16. The method of claim 15, comprising:
the third parallel corresponding to electrically connecting a first positive terminal of the first cluster and a second positive terminal of the second cluster together as a common positive terminal and electrically connecting a first negative terminal of the first cluster and a second negative terminal of the second cluster together as a common negative terminal; and
utilizing the common positive terminal and the common negative terminal as output terminals of the formed thin-film based thermoelectric module.

17. The method of claim 15, further comprising:
printing and etching a design pattern of metal onto the each of the first surface and the second surface of the flexible substrate to form electrically conductive pads, leads and terminals on the flexible substrate corresponding to each of the first cluster and the second cluster, the formed electrically conductive pads, the leads and the terminals having a dimensional thickness less than or equal to 18 μm;
additionally electrodepositing a seed metal layer comprising at least one of: Cr, Ni and Au directly on top of the formed electrically conductive pads, the leads and the terminals on the flexible substrate following the printing and etching thereof, the seed metal layer having a dimensional thickness less than or equal to 5 μm; and
sputter depositing the pairs of the N-type thermoelectric legs and the P-type thermoelectric legs of the each of the first cluster and the second cluster directly on top of the electrodeposited seed metal layer.

18. The method of claim 15, further comprising encapsulating the formed thin-film based thermoelectric module with an elastomer to render the flexibility thereto, the elastomer providing an encapsulation having a dimensional thickness less than or equal to 15 μm.

19. The method of claim 18, comprising the elastomer being silicone.

20. The method of claim 19, further comprising:
loading the silicone with nano-size Al2O3 powder to enhance thermal conductivity thereof to aid heat transfer across the formed thin-film based thermoelectric module.
